(19) United States
(12) Patent Application Publication
(10) Pub. No.: US 2024/0276649 A1
(43) Pub. Date: Aug. 15, 2024

(54) POWER SUPPLY MODULE AND METHOD OF ASSEMBLY

(71) Applicant: Advanced Energy Industries, Inc., Denver, CO (US)

(72) Inventors: Antonios Tzimas, Worthing (GB); Mohit Chirodian, Rustington (GB); Keith Garlish, Rustington (GB)

(21) Appl. No.: 18/108,094

(22) Filed: Feb. 10, 2023

(51) Int. Cl. H05K 3/28; H05K 1/18

(52) U.S. Cl. CPC H05K 3/284; H05K 1/18; H05K 2201/2036

(57) ABSTRACT

A method for assembling a power supply module, wherein a plurality of spacers are positioned between planes of different electrical potential on at least a high voltage end of a printed circuit board (PCB). The plurality of spacers having an electric field of a creepage distance greater than 0.4 kV/mm and configured to mechanically support the PCB during assembly and curing of an encapsulant. The encapsulant being an insulating material configured to provide electrical and thermomechanical insulation to the power supply module.

### BACKGROUND

### Field

The present disclosure relates generally to power supplies, and more specifically to encapsulated spacers for use in high voltage power supply modules.

### Background

High voltage power supply modules typically comprise encapsulated electrical components and are commonly used to generate direct current (DC) and alternating current (AC) outputs. These increasingly complex systems are typically assembled with rigid spacers that often lead to problematic warping of printed circuit boards assemblies (PCBAs) that expediently accept standards that are lower than is desirable, compromise clearing distances to ground, and lead to premature breakdown of encapsulating materials, and large housings to increase the clearance distances of the PCBAs from ground. Thus, there is a need for a more efficient and compact high voltage power supply module.

### SUMMARY

An aspect may be characterized as a method of assembling a power supply module, the method including: positioning a plurality of spacers between planes of different electrical potential on at least a high voltage end of a printed circuit board (PCB), the plurality of spacers having an electric field of a creepage distance greater than 0.4 kV/mm and configured to at least structurally support the PCB during assembly; and encasing the PCB and the plurality of spacers in an encapsulant included of an insulating material configured to insulate the PCB thermally and electrically.

Another aspect may be characterized as an electronic system including: one or more power supply modules, wherein each power supply module includes: a printed circuit board (PCB); an encapsulant having thermal and electrical insulation properties and configured to encase the PCB; and a plurality of spacers having an electrical field of a creepage distance greater than 0.4 kV/mm and positioned within the encapsulant at least at a high voltage end of the PCB.

Yet another aspect may be characterized as a power supply module including: an electronic assembly including a plurality of spacers having an electric field of a creepage distance greater than 0.4 kV/mm, and one or more electrical components coupled to the electronic assembly; an encapsulant included of an insulating material and configured to encase the a electronic assembly; and at least one housing configured to contain the electronic assembly and define an area for enclosing the encapsulant.

### BRIEF DESCRIPTION OF THE DRAWINGS

FIG. 1 is an exemplary power supply module with a plurality of encapsulated spacers in accordance with the assembly methodologies described herein;

FIG. 2 depicts a spacer that may be positioned on a power supply module and operate according to the assembly methodologies described herein;

FIG. 3 is a front view of the spacer depicted in FIG. 2;

FIG. 4 is a bottom perspective view of the spacer depicted in FIG. 2;

FIG. 5 is a top view of the spacer depicted in FIG. 2;

FIG. 6A is a second view of an exemplary power supply module with a plurality of encapsulated spacers in accordance with the assembly methodologies described herein;

FIG. 6B is a view of an exemplary PCB with a plurality of receiving apertures;

FIG. 7 depicts an exemplary power supply module with at least one encapsulated spacer affixed to a PCB on a high voltage end of the PCB and a plurality of rigid spacers affixed to the PCB on a low voltage end of the PCB in accordance with the assembly methodologies described herein;

FIG. 8 depicts an exemplary power supply module with at least one encapsulated spacer affixed to at least one electrical component on a PCB at a high voltage end of the PCB in accordance with the assembly methodologies described herein;

FIG. 9 depicts an exemplary spacer positioned within planes of different electrical potential on a PCB and encased within an encapsulant in accordance with the assembly methodologies described herein;

FIG. 10 is a second view of the encapsulated spacer depicted in FIG. 9;

FIG. 11 is a third view of the encapsulated spacer of FIG. 9 depicting the creepage distance of the encapsulated spacer between the planes of different electrical potential; and

FIG. 12 shows a flowchart depicting a method that may be traversed in connection with embodiments disclosed herein.

### DETAILED DESCRIPTION

High voltage power supply modules rely on increasingly sophisticated material compositions and structural assembly variations to provide adequate clearances. Conventional electrical components of high voltage power supply modules are encapsulated within solid polymeric insulation to provide electrical isolation from surfaces having different electrical potential. Encapsulating electrical components in high voltage power supply modules allows for more compact designs since the withstand voltages of the encapsulation material are much greater than air.

High voltage assemblies, such as PCBAs, vary in length and width. Some PCBAs are around 700 mm in length and 400 mm in width and commonly, exclusively, comprise rigid spacers positioned at high voltage and low voltage ends of the assembly. However, these rigid spacers often increase malleability of PCBAs resulting in assemblies that are highly susceptible to twisting and flexing, especially at their high voltage ends. Twisting and flexing is undesirable and often results in compromised clearance distances to ground as usually the high voltage end of the PCBAs approach shorter distances to ground as they bend, which reduces the voltage withstand capabilities of the entire high assembly. Furthermore, when the voltage withstand capabilities of the high voltage power supply module decreases, the susceptibility of the encapsulating material also increases, and this increase often leads to premature failure of the encapsulating material as well. Some conventional systems have attempted to curtail this undesirable outcome by increasing the clearances of the PCBAs, but this solution exclusively utilizes rigid spacers affixed to both ends of the PCBA and results in larger, bulkier assemblies. Thus, there is currently a need for a more compact power supply module configured to maintain clearance from the PCBA to ground on both ends of the PCBA during assembly of the power supply module and during curing of the encapsulant.

The word “exemplary” is used herein to mean “serving as an example, instance, or illustration.” Any embodiment described herein as “exemplary” is not necessarily to be construed as preferred or advantageous over other embodiments.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items, and may be abbreviated as “/”.

Embodiments of the disclosure are described herein with reference to cross-section illustrations that are schematic illustrations of idealized embodiments (and intermediate structures) of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of the disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

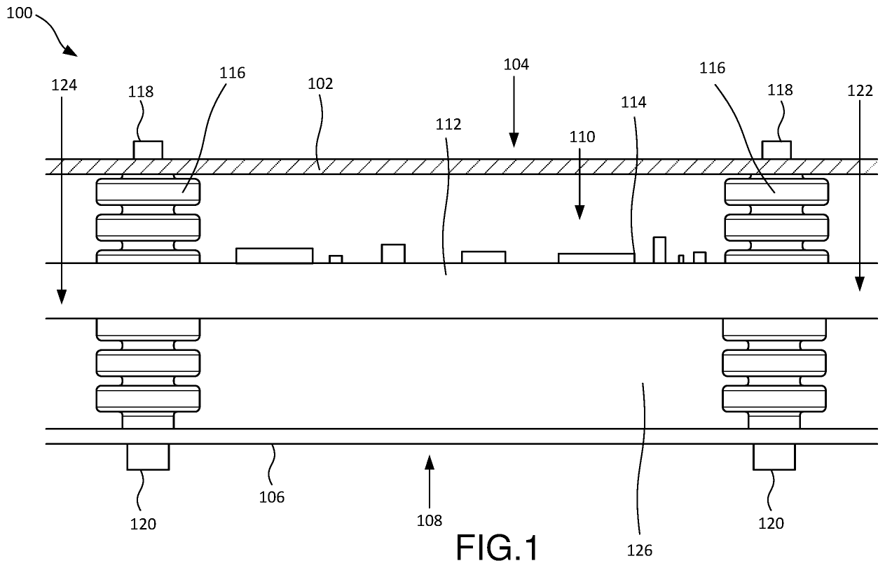

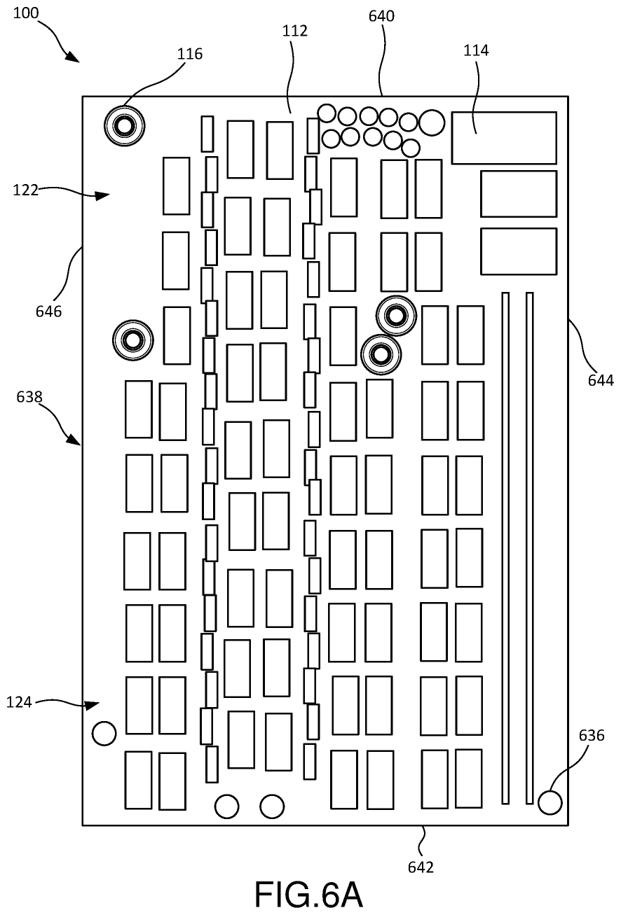

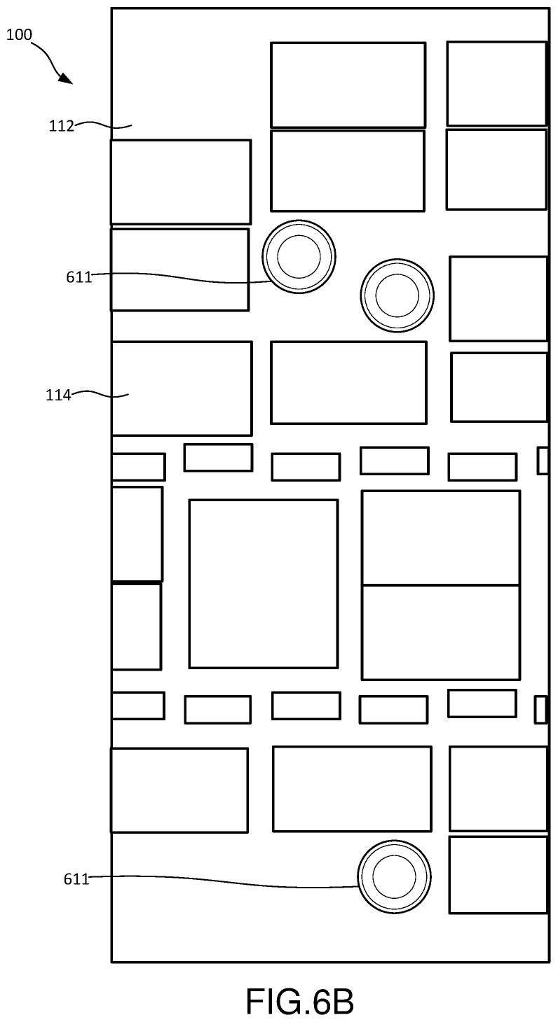

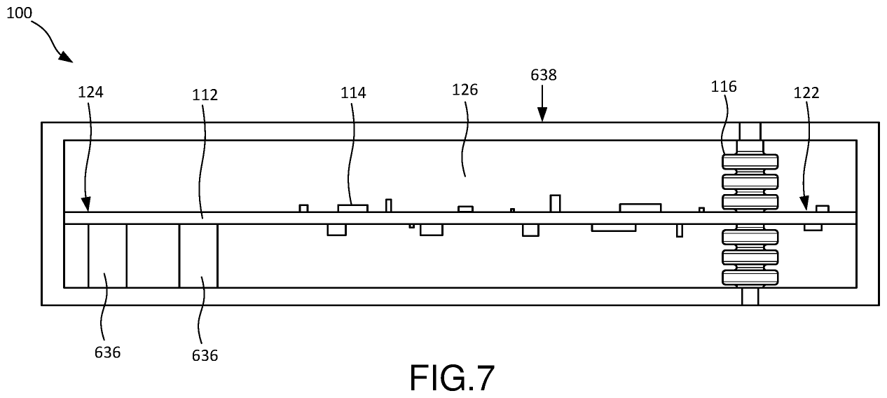

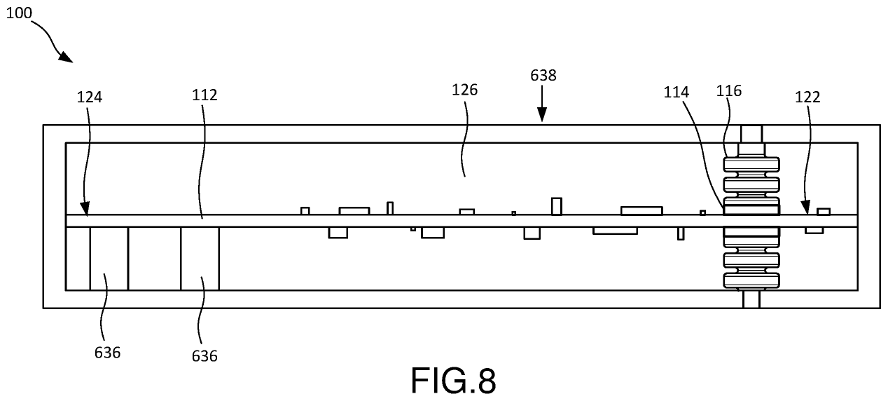

Referring to FIG. 1, shown is an exemplary power supply module (electronic assembly or electronic system) 100 in accordance with aspects of this disclosure. As shown, the power supply module 100 may comprise at least two planes, for example, a first plane 102 having a first electrical potential (e.g., voltage withstand capability), and a second plane 106 having a second electrical potential that is the same or different from the first plane 102. The first plane 102 and second plane 106 may be comprised of a conductive or non-conductive material. In some non-limiting embodiments, the first plane 102 and the second plane 106 define an upper surface 104 and a lower surface 108 of a housing (e.g., a potting box) (e.g., see housing 638 described with reference to FIGS. 7-8), respectively. The housing 638 may further comprise a first side plane (e.g., see first side plane 640 described with reference to FIG. 6A), a second side plane (e.g., see second side plane 642 described with reference to FIG. 6A), a third side plane (e.g., see third side plane 644 described with reference to FIG. 6A), and a fourth side plane (e.g., see fourth side plane 646 described with reference to FIG. 6A), collectively regarded as a plurality of side planes. Together the first plane 102, the second plane 106, and the plurality of side planes may define an interior 110 of the power supply module 100. The interior 110 may function to define an area for enclosing the encapsulant 126 and limiting the volume of encapsulant 126 capable of being introduced into the power supply module 100.

Also shown in FIG. 1 is a printed circuit board (PCB) 112 positioned within the interior 110 of the power supply module 100. The PCB 112 may comprise one or more electrical components 114 affixed to at least one surface of the PCB 112 that function as part of the power supply module 100. The depicted PCB 112 may further comprise one or more aperture(s) (e.g., see apertures 611 described with reference to FIG. 6B) that function to receive and secure a plurality of spacers 116 to the PCB 112.

The plurality of spacers 116 may further comprise a first end 118 and a second end 120, wherein the first end 118 engages with an aperture (not shown) formed on the first plane 102 of the power supply module 100, and the second end 120 engages with a second aperture (not shown) formed on the second plane 106 of the power supply module 100. In some cases, the plurality of spacers 116 may be slotted or affixed by other means to the PCB 112 at a high voltage end 122 and a low voltage end 124 of the PCB 112. In other embodiments, the plurality of spacers 116 may be slotted or affixed by other means only to the high voltage end 122 of the PCB 112, while traditional, rigid spacer(s) (e.g., see rigid spacers 636 described with reference to FIG. 6A) are slotted or affixed by other means to the low voltage end 124 of the PCB 112. In yet other embodiments, the plurality of spacers 116 may be slotted or affixed by other means to both the high voltage end 122 and the low voltage end 124 of the PCB 112 and slotted or affixed by other means to the PCB 112 on other attachment positions configured to provide mechanical support of the PCB 112 during assembly. Additionally, or alternatively, the plurality of spacers 116 may be slotted or affixed by other means to the one or more electrical components 114 on the PCB 112. The plurality of spacers 116 may extend vertically from the second plane 106, through the PCB 112, to the first plane 102, or extend from the second plane 106 and terminate at the PCB 112. Alternatively, the plurality of spacers 116 may extend vertically from the first plane 102, through the PCB 112, to the second plane 106, or extend from the first plane 102 and terminate at the PCB 112.

Also shown in FIG. 1 is the encapsulant 126 that fully encapsulates (also referred to as encases) the various components contained within the power supply module 100. In some embodiments the encapsulant 126 functions to provide electrical isolation of the encapsulated components in both low and high voltage environments. The depicted encapsulant 126 may be comprised of a polymeric insulating material such as epoxies, silicones, or polyurethanes, but is not limited in its composition. In some instances, the encapsulant 126 may cure in ambient temperatures, while in other instances the encapsulant may cure at 6° C. and upon curing may function to withstand electrical and thermomechanical stresses during operation of the power supply module 100.

In some embodiments the encapsulant 126 is poured or added to the interior 110 of the housing (e.g., see housing 638 described with reference to FIG. 6A) after the plurality of spacers 116 are positioned on or affixed to the PCB 112 or the one or more electrical components 114. In yet other embodiments, the encapsulant 126 is poured or added to a first half of the interior 110 of the housing and allowed to completely or partially cure or harden prior to being poured or added to a second half of the interior 110. Additionally, or alternatively, subsequent to pouring or adding the encapsulant 126 to the interior 110 of the housing, the power supply module may be placed in a vacuum chamber configured to remove trapped air or gasses within the encapsulant 126. Then, in some instances, a jig or other compression means (not shown) may be implemented to exert pressure on the first plane 102 in an inward direction relative to the PCB 112 and second plane 106 and/or on the second plane 106 in an inward direction relative to the PCB 112 and first plane 102. The pressure from the compression means may function to ensure that the PCB 112 and the plurality of spacers 116 within the power supply module 100 remain in place during curing of the encapsulant 126.

In some instances, the first end 118 and the second end 120 of the spacer 116 may extend through the upper surface 104 and lower surface 108 of the power supply module 100, respectively, and form one or more coupling members configured to detachably couple the power supply module 100 to one or more second power supply modules (not shown).

Alternatively, coupling members may extend from the PCB 112 through the upper surface 104 and lower surface 108 of the power supply module 100 or may be formed, joined or otherwise directly affixed to the upper surface 104 and lower surface 108 of the power supply module 100.

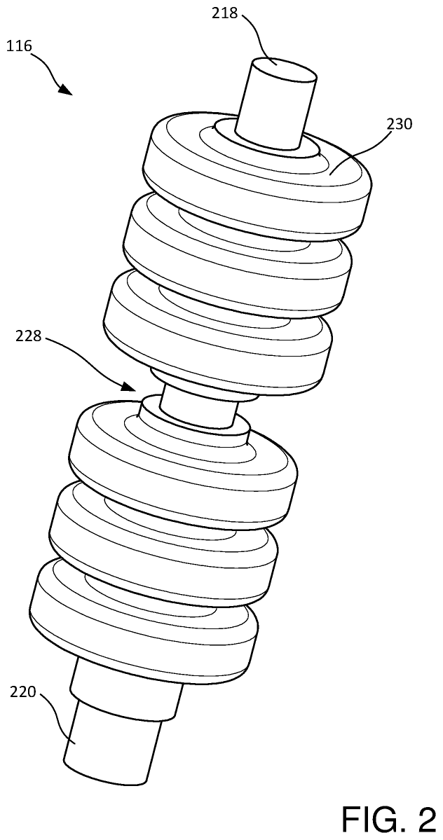

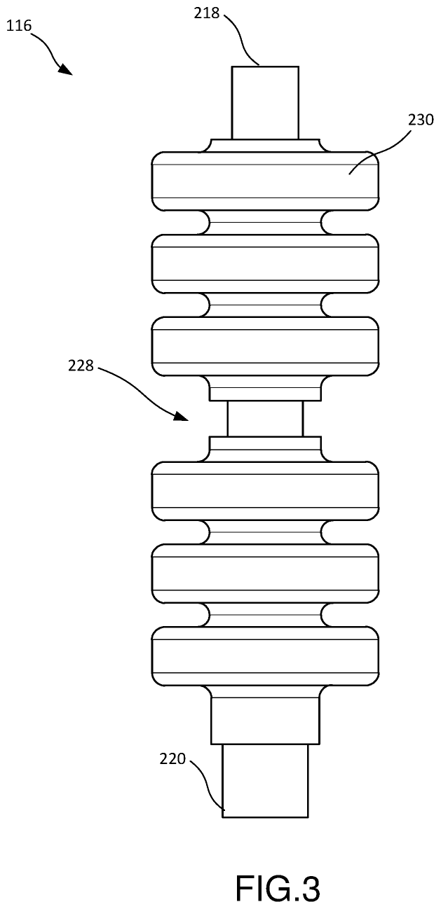

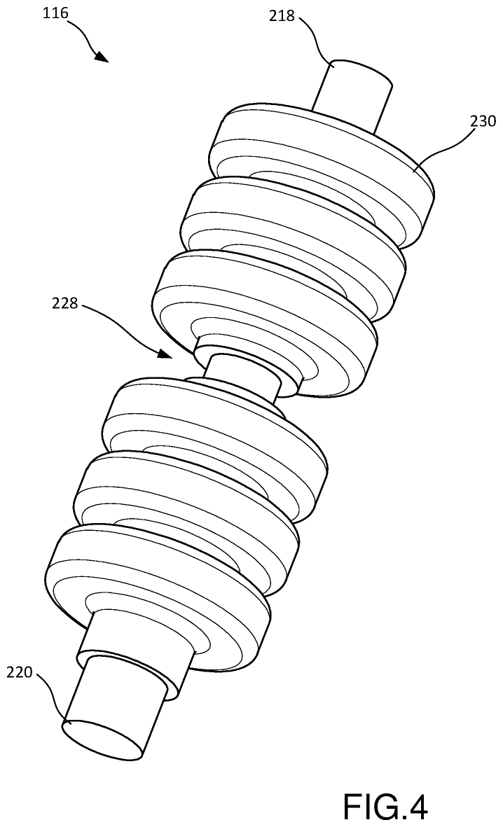

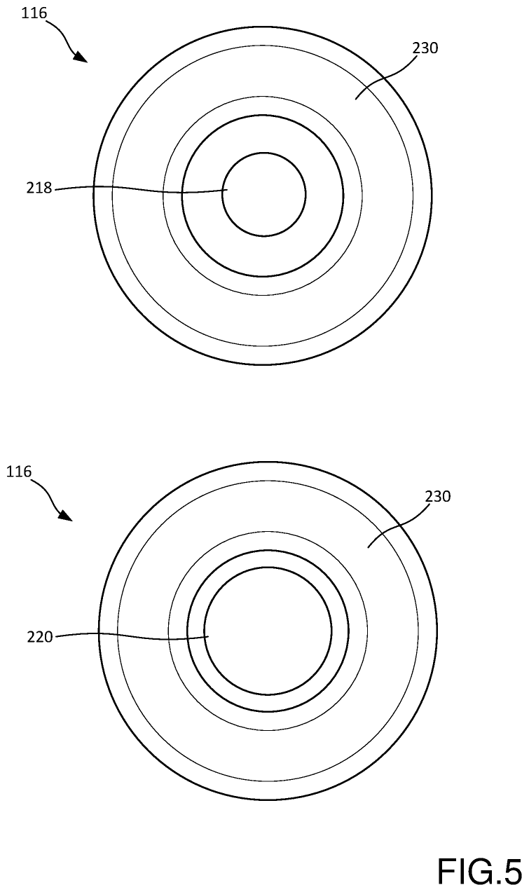

Referring next to FIGS. 2-5, shown is a single spacer 116 in accordance with an embodiment of the present disclosure. In the illustrated embodiment, the spacer 116 comprises a core 228, a plurality of sheds 230, a first end 218 having a first diameter, and a second end 220 having a second diameter. The spacer 116 may be comprised of the same insulating material as the encapsulant 126. In other instances, the spacer 116 may be comprised of an insulating material that is dissimilar to the insulating material of the encapsulant 126 as long as the insulating material has similar electrical and mechanical properties as the insulating material of the encapsulant. In some embodiments, the spacer 116 may be comprised of an insulating material with a modified mixing ratio that includes a greater amount of hardener or hardening agent than the insulation material used in the encapsulant 126. In some cases, the hardness of the spacer 116 is between 65-70 (Shore A), while the hardness of the encapsulant 126 may be between 45-50 (Shore A). The insulation material with additional hardener functions to provide sufficient mechanical support of the PCB (e.g., the PCB 112 of FIG. 1) during assembly and curing of the encapsulant 126 to prevent bowing, flexing or warping of the PCB 112. Being formed of the same insulating material reduces the risk of mechanical searing at interface points or contact surfaces between the spacer 116 and the surrounding encapsulant 126. Moreover, tracking and dielectric breakdown is also reduced as the insulating material has matching coefficients of thermal expansion (CTE).

As shown in FIGS. 2-4, the first end 218 of the spacer 116 may have a diameter that is dissimilar to the second end 220 of the spacer 116. In these instances, the variable diameters may function to assists in placement and orientation of the spacer 116 within the planes of the power supply module (e.g., see power supply module 100 of FIG. 1), wherein the first end 218 is configured to engage with the first plane (e.g., see first plane 102 of FIG. 1) and the second end 220 is configured to engage with the second plane 106. This configuration is non-limiting and the first diameter of the first end 218 and the second end 220 may be the same and thus interchangeable in the power supply module 100.

Referring to FIGS. 6A-6B, shown is a top view of a power supply module 100 with a plurality of spacers 116 according to another embodiment of the present disclosure. As illustrated, the power supply module 100 comprises a PCB 112 having a high voltage end 122 and a low voltage end 124, and one or more electrical components 114 and rigid spacers 636 affixed to its surface. As shown in FIG. 6A, the power supply module 100 is contained within a housing 638 having a first side plane 640, a second side plane 642, a third side plane 644, and a fourth side plane 646. The illustrated embodiment further depicts the power supply module 100 prior to pouring or adding encapsulant (e.g., see encapsulant 126 described with reference to FIG. 1) to the system. As shown, the PCB 112 may further comprise one or more aperture(s) 611 (also referred to as receiving apertures 611) that function to receive and secure the plurality of spacers 116 to the PCB 112. The plurality of apertures may comprise tracks for the plurality of spacers 116 to slot into the PCB or may be formed to allow for other means of slotting the plurality of spacers 116 to the PCB 112.

Referring next to FIGS. 7-8, shown is an elevation view of a power supply module 100 filled with an encapsulant 126 and comprising at least one encapsulated spacer 116. Further illustrated is a plurality of rigid spacers 636 affixed to the PCB 112 on a low voltage end 124 of the PCB 112 and a one or more electrical components 114 affixed to the PCB 112. FIG. 7 illustrates the spacer 116 slotted or affixed by other means to the PCB 112 on a high voltage end 122 of the PCB 112, while FIG. 8 depicts the spacer 116 slotted or affixed by other means directly to the one or more electrical components 114 affixed to the PCB 112. In some embodiments, the spacer 116 may be formed of two halves, wherein the first half is configured to affix to the one or more electrical components 114, while the second half is configured to join or affix to the PCB 112.

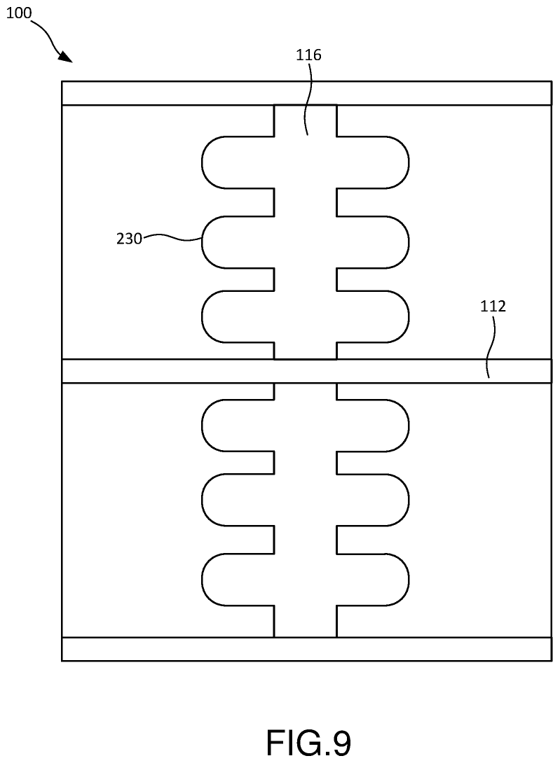

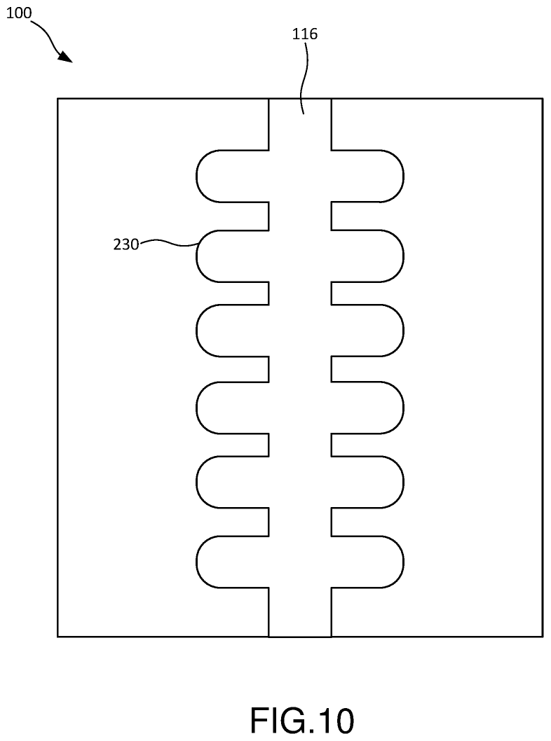

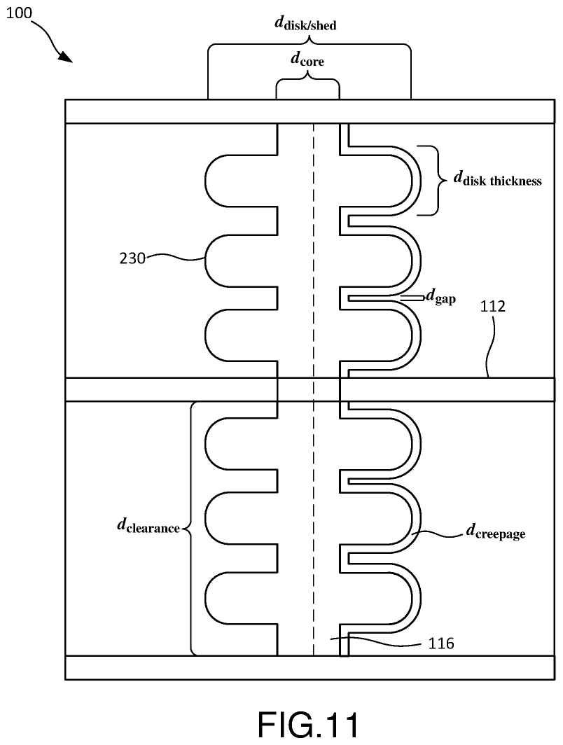

Referring to FIGS. 9-11, illustrated is an exemplary spacer 116 affixed to a PCB 112 and encapsulated within a power supply module 100, as referenced in FIG. 1. As shown in FIG. 2, the sheds 230 are disk-shaped components of the spacer 116 that are designed with a geometry and relative positioning to enhance electrical withstand performance of the dielectric interface formed of the spacer 116 and the encapsulant 126. The geometry of the sheds 230 is rounded at the outer edges and inner edges to minimize the electric field of the sheds 230 and the spacer 116. The spacer 116 of FIG. 11 shows the creepage distance d_{creepage} and clearance distance d_{clearance} of the spacer 116 within the power supply module 100. As shown, the d_{creepage} is at least greater than the d_{clearance}. The d_{creepage} and d_{clearance} may vary but in many embodiments the electric field of the d_{creepage} is at least be greater than 0.4 kV/mm. In some embodiments the electric field of the creepage distance is at least 2 kV/mm. Additionally, in some embodiments the spacer 116 has a core diameter d_{core} that is less than a diameter of the sheds d_{disk/shed} (disk diameter). In some embodiments the power supply module 100 comprises a plurality of sheds 230 wherein the disk diameter d_{disk/shed} defines the creepage distance d_{creepage} along a surface of each shed 230. Further illustrated is the distance between two of the sheds 230 of the spacer 116, represented by d_{gap}, and the thickness of each of the disks or sheds 230, represented by d_{disk thickness}.

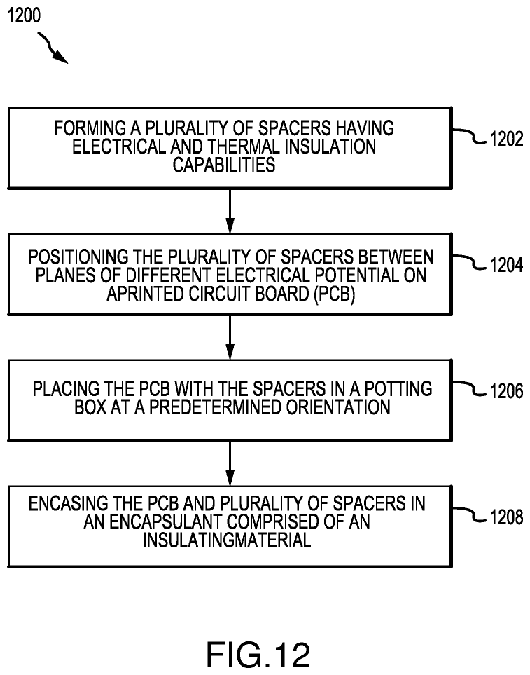

Referring next to FIG. 12, shown is a flowchart depicting a method 1200 that may be traversed in connection with embodiments disclosed herein. At step 1202, a plurality of spacers 116 having electrical and thermal insulation properties may be formed of an insulating material. At step 1204, the plurality of spacers 116 may be positioned between planes 102, 106 of different electrical potential on a PCB 112. At step 1206, the PCB 112 with the plurality of spacers 116 may be positioned in a housing 638 at a predetermined orientation. Finally, at step 1208, the PCB 112 with the plurality of spacers 116 may be encapsulated by an encapsulant 126, wherein the encapsulant 126 may be comprised of the same insulating material as the plurality of spacers 116.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A method of assembling a power supply module, the method comprising:
positioning a plurality of spacers between planes of different electrical potential on at least a high voltage end of a printed circuit board (PCB), the plurality of spacers having an electric field of a creepage distance greater than 0.4 kV/mm and configured to at least mechanically support the PCB during assembly; and
encapsulating the PCB and the plurality of spacers in an encapsulant comprised of an insulating material.

2. The method of claim 1, wherein the PCB comprises one or more receiving apertures, and the plurality of spacers are slotted in the one or more receiving apertures of the PCB.

3. The method of claim 1, wherein the PCB comprises one or more electrical components, and the plurality of spacers are affixed to the one or more electrical components of the PCB.

4. The method of claim 1, further comprising:
forming a housing configured to contain the PCB, the plurality of spacers, and the encapsulant;
positioning the PCB and the plurality of spacers in the housing prior to encapsulating; and
applying pressure to the encapsulant during curing.

5. The method of claim 4, wherein the encapsulating comprises applying encapsulant to an interior of the housing to immerse a first side of the PCB with encapsulant and subsequently immersing a second side of the PCB, opposite of the first side.

6. The method of claim 1, further comprising:
forming the plurality of spacers from the insulating material with a greater amount of hardening agent than a ratio used for the encapsulant.

7. The method of claim 1, wherein the electric field of the creepage distance is at least 2 kV/mm.

8. The method of claim 1, further comprising:
forming one or more coupling members configured to detachably couple the power supply module to one or more second power supply modules.

9. An electronic system comprising:
one or more power supply modules, wherein each power supply module comprises:
a housing comprising at least two planes, wherein a first plane defines an upper surface, and a second plane defines a lower surface of the housing;
a printed circuit board (PCB) positioned between at least the upper surface and the lower surface;
a plurality of spacers positioned on at least a high voltage end of the PCB and configured to engage with at least one plane of the at least two planes, wherein each spacer of the plurality of spacers has an electric field of a creepage distance greater than 0.4 k V/mm; and
an encapsulant comprised of an insulating material and configured to encapsulate the PCB and the plurality of spacers.

10. The electronic system of claim 9, wherein each spacer of the plurality of spacers comprises:
a plurality of disks having a disk diameter defining the creepage distance along a surface of each disk,
a core having a core diameter less than the disk diameter,
a first end configured to engage with the upper surface of the housing, and
a second end configured to engage with the lower surface of the housing.

11. The electronic system of claim 10, wherein the electric field of the creepage distance is 2 k V/mm.

12. The electronic system of claim 10, wherein the housing further comprises:
an interior comprised of the first plane, the second plane, and a plurality of side planes, wherein the plurality of side planes comprise:
a first side plane of the housing,
a second side plane of the housing,
a third side plane of the housing, and
a fourth side plane of the housing.

13. The electronic system of claim 12, wherein the plurality of spacers further comprise a ratio of hardening agent greater than the ratio of hardening agent in the electrical insulating material of the encapsulant to prevent warping of the PCB at least at the high voltage end.

14. A power supply module comprising:
a housing comprising at least two planes, wherein a first plane defines an upper surface, and a second plane defines a lower surface of the housing;
an electronic assembly comprising one or more electrical components coupled to at least one surface of the electronic assembly;
a plurality of spacers positioned on the electronic assembly, the plurality of spacers comprising:
a plurality of disks having a disk diameter defining a creepage distance along a surface of each disk,
a core having a core diameter less than the disk diameter,
a first end configured to engage with the upper surface of the housing,
a second end configured to engage with the lower surface of the housing, and
an electric field of the creepage distance greater than 0.4 kV/mm; and
an encapsulant comprised of an insulating material and configured to encapsulate the electronic assembly and plurality of spacers.

15. The power supply module of claim 14, wherein the electric field of the creepage distance is 2 kV/mm.

16. The power supply module of claim 14, the plurality of spacers are comprised of the insulating material with a greater amount of hardening agent than a ratio used for the encapsulant.

17. The power supply module of claim 16, wherein the plurality of spacers are affixed to the one or more electrical components of the electronic assembly.

18. The power supply module of claim 14, further comprising one or more coupling members configured to detachably couple the power supply module to one or more second power supply modules.

19. The power supply module of claim 14, wherein the insulating material is configured to prevent breakdown of the encapsulant at a contact surface of the plurality of spacers and the encapsulant when a voltage is introduced across the contact surface of the plurality of spacers.

20. The power supply module of claim 19, wherein the electronic assembly is a printed circuit board (PCB) and the plurality of spacers are positioned on the PCB at least at a high voltage end of the PCB, wherein the plurality of spacers are further configured to prevent warping of the PCB during assembly and curing of the encapsulant.
